(19) United States
(12) Patent Application Publication
(10) Pub. No.: US 2026/0006884 A1
(43) Pub. Date: Jan. 1, 2026

(54) GATE-CONTROLLED SEMICONDUCTOR DEVICES HAVING TEMPERATURE COMPENSATED GATE RESISTANCES

(71) Applicant: Wolfspeed, Inc., Durham, NC (US)

(72) Inventor: Thomas Harrington, Durham, NC (US)

(21) Appl. No.: 18/755,884

(22) Filed: Jun. 27, 2024

(51) Int. Cl. H01L 29/43

(52) U.S. Cl. CPC H10D 64/605

(57) ABSTRACT

Semiconductor devices comprise a semiconductor layer structure and a gate structure that comprises a high resistance portion and a low-resistance portion on the semiconductor layer structure. The high resistance portion of the gate structure comprises a first section that has a first resistance temperature coefficient and a second section that has a second resistance temperature coefficient that differs from the first resistance temperature coefficient.

### FIELD

The present invention relates to semiconductor devices and, more particularly, to semiconductor devices having gate resistors.

### BACKGROUND

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region and a drain region are formed in the semiconductor layer structure that are separated by a channel region. A gate electrode is disposed adjacent the channel region and separated from the channel region by a thin oxide layer. A MOSFET may be turned on or off by setting a bias voltage that is applied to the gate electrode to be above or below a threshold value. When a MOSFET is turned on (i.e., it is in its “on-state”), current is conducted through the channel region between the source and drain regions. When the bias voltage is reduced below the threshold level, the current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other circuit devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT. An IGBT may be implemented, for example, as a Darlington pair that includes a high voltage n-channel MOSFET at the input and a BJT at the output. The base current of the BJT is supplied through the channel of the MOSFET, thereby allowing a simplified external drive circuit (since the drive circuit only charges and discharges the gate electrode of the MOSFET).

In many applications, MOSFETs may need to conduct large currents and/or be capable of blocking high voltages (e.g., hundreds or thousands of volts of electric potential). Such MOSFETs are often referred to as “power” MOSFETs. Power MOSFETs are often fabricated from wide band-gap semiconductor materials (herein, the term “wide band-gap semiconductor” encompasses any semiconductor material having a band-gap of at least 1.4 eV). Power semiconductor devices are often formed in silicon carbide (“SiC”), which has a number of advantageous characteristics including, for example, a high electric field breakdown strength, high thermal conductivity, high electron mobility, high melting point and high-saturated electron drift velocity

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure. In contrast, in a device having a vertical structure, at least one terminal is provided on each major surface of the semiconductor layer structure (e.g., in a vertical MOSFET, the source and gate may be on the top surface of the semiconductor layer structure and the drain may be on the bottom surface of the semiconductor layer structure). The semiconductor layer structure may or may not include an underlying substrate such as a growth substrate.

The semiconductor layer structure of a power semiconductor device typically includes an “active region” in which one or more functional semiconductor devices are formed. The active region acts as a main junction for blocking voltage during reverse bias (off-state) operation and for providing current flow during forward bias (on-state) operation. The power semiconductor device may also have an edge termination structure such as guard rings or a junction termination extension in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will typically have its own edge termination structure. After the wafer is fully processed, the resultant structure may be diced to separate the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

Many power semiconductor devices, such as power MOSFETs and IGBTs, Junction Field Effect Transistors (“JFETs”) and gate-controlled thyristors, have gate structures. These devices can be turned on and off by applying different bias voltages to the gate structures thereof. Herein, power semiconductor devices that include a gate structure are referred to as “gate-controlled” power semiconductor devices.

Vertical gate-controlled power semiconductor devices can have a planar gate electrode design in which the gate electrodes are formed on top of the semiconductor layer structure or, alternatively, may have the gate electrodes formed within gate trenches in the semiconductor layer structure, which are typically referred to as gate trench devices. With the planar gate electrode design, the channel region of each unit cell transistor is horizontally disposed underneath the gate electrode. In contrast, in gate trench devices, the channels are typically vertically disposed adjacent sidewalls of the gate electrodes. Gate trench devices may provide enhanced performance, but typically require a more complicated manufacturing process.

The gate structure of a gate-controlled power semiconductor device has a distributed gate resistance, which is a function of the length of the electrical path from the gate pad (or other gate terminal) to the gate electrode (also referred to herein as gate fingers) of each individual unit cell and the sheet resistance of the materials forming the gate structure. The gate structure may comprise, for example, the gate pad, a plurality of gate electrodes in the active region of the device, one or more gate buses that extend between the gate pad and the gate electrodes, and optional gate runners that may be positioned between the gate bus(es) and the gate electrodes. In many applications, it may be desirable to increase the amount of the gate resistance by, for example, adding a discrete or “lumped” gate resistor somewhere within the gate structure. The increased gate resistance may, for example, be used to limit the switching speed of the device or to reduce electrical ringing and/or noise.

### SUMMARY

Pursuant to embodiments of the present invention, semiconductor devices are provided that comprise a semiconductor layer structure and a gate structure that comprises a high resistance portion and a low-resistance portion on the semiconductor layer structure. The high resistance portion of the gate structure comprises a first section that has a first resistance temperature coefficient and a second section that has a second resistance temperature coefficient that differs from the first resistance temperature coefficient.

In some embodiments, the second resistance temperature coefficient may be at least 25% less than the first resistance temperature coefficient.

In some embodiments, the first section of the high resistance portion of the gate structure comprises a plurality of gate electrodes that are on an active region of the semiconductor layer structure and the second section of the high resistance portion of the gate structure comprises a lumped gate resistor. In some embodiments, the gate structure further comprises a metal portion that comprises a gate pad, and the lumped gate resistor is interposed on an electrical path between the gate pad and at least some of the gate electrodes.

In some embodiments, the first section of the high resistance portion of the gate structure comprises a first material and the second section of the high resistance portion of the gate structure comprises a second material that is different from the first material. In some embodiments, the first material is doped polysilicon and the second material comprises metal-silicon alloy.

In some embodiments, the first section of the high resistance portion of the gate structure comprises a first semiconductor material that has a first doping concentration and the second section of the high resistance portion of the gate structure comprises the first semiconductor material that has a second doping concentration that is less than the first doping concentration. In some embodiments, the first semiconductor material comprises polysilicon. In some embodiments, the first section of the high resistance portion of the gate structure comprises a plurality of gate electrodes that are on an active region of the semiconductor layer structure and the second section of the high resistance portion of the gate structure comprises a lumped gate resistor that is on an inactive region of the semiconductor layer structure.

In some embodiments, the first section of the high resistance portion of the gate structure comprises a first semiconductor material that is doped with a first dopant type and the second section of the high resistance portion of the gate structure comprises the first semiconductor material that is doped with a second dopant type.

In some embodiments, the first section of the high resistance portion of the gate structure represents at least 10% of a total sheet resistance of the gate structure and the second section of the high resistance portion of the gate structure represents at least 10% of the total sheet resistance of the gate structure.

In some embodiments, the first section of the high resistance portion of the gate structure has a positive resistance temperature coefficient and the second section of the high resistance portion of the gate structure has a negative resistance temperature coefficient.

In some embodiments, the first section of the high resistance portion of the gate structure has a first positive resistance temperature coefficient and the second section of the high resistance portion of the gate structure has a second positive resistance temperature coefficient that is less than half the first positive resistance temperature coefficient.

In some embodiments, the first section of the high resistance portion of the gate structure comprises a plurality of gate electrodes that are on an active region of the semiconductor layer structure and the second section of the high resistance portion of the gate structure comprises a lumped gate resistor that is on an inactive region of the semiconductor layer structure, and wherein the gate structure further comprises a metal portion that comprises a metal gate pad and a metal gate bus. In some embodiments, the metal gate pad is electrically connected to the metal gate bus through the lumped gate resistor, and at least some of the gate electrodes are electrically connected to the lumped gate resistor through the metal gate bus.

In some embodiments, the gate structure has a gate resistance that varies by less than 6% per 100° C. over an operating temperature range of the semiconductor device.

In some embodiments, the semiconductor layer structure comprises at least one wide bandgap semiconductor layer. In some embodiments, the semiconductor device comprises a field effect transistor. In some embodiments, the first section of the high resistance portion of the gate structure comprises a plurality of gate electrodes that are at least partly within gate trenches in an active region of the semiconductor layer structure and the second section of the high resistance portion of the gate structure comprises a lumped gate resistor that is on an inactive region of the semiconductor layer structure.

Pursuant to further embodiments of the present invention, semiconductor devices are provided that comprise a semiconductor layer structure and a gate structure on the semiconductor layer structure, the gate structure comprising a plurality of gate electrodes and at least one lumped gate resistor. The gate electrodes comprise a first material and the at least one lumped gate resistor comprises a second material that is different from the first material.

In some embodiments, the gate structure further comprises a metal portion that comprises a gate pad, and the lumped gate resistor is interposed on an electrical path between the gate pad and at least some of the gate electrodes. In some embodiments, the first material is doped polysilicon and the second material comprises silicon-chromium. In some embodiments, the first material is doped polysilicon and the second material has a resistance temperature coefficient that is at least 25% less than a resistance temperature coefficient of the doped polysilicon.

In some embodiments, the first material has a positive resistance temperature coefficient and the second material has a negative resistance temperature coefficient.

In some embodiments, the first material has a first positive resistance temperature coefficient and the second material has a second positive resistance temperature coefficient that is less than half the first positive resistance temperature coefficient.

In some embodiments, the gate structure has a gate resistance that varies by less than 6% per 100° C. over an operating temperature range of the semiconductor device.

In some embodiments, the semiconductor layer structure comprises at least one wide bandgap semiconductor layer.

Pursuant to additional embodiments of the present invention, semiconductor devices are provided that comprise a semiconductor layer structure and a gate structure that comprises a semiconductor portion on the semiconductor layer structure. The semiconductor portion of the gate structure comprises a first section that comprises a first semiconductor material and that has a first doping concentration and a first dopant type and a second section that comprises the first semiconductor material and has a second doping concentration and a second dopant type, where second doping concentration is less than the first doping concentration and/or the second dopant type is different than the first dopant type.

In some embodiments, the first section of the gate structure has a first resistance temperature coefficient and the second section of the gate structure has a second resistance temperature coefficient that is at least 25% less than the first resistance temperature coefficient.

In some embodiments, the first section of the gate structure comprises a plurality of gate electrodes that are on an active region of the semiconductor layer structure and the second section of the gate structure comprises one or more lumped gate resistors. In some embodiments, the gate structure further comprises a metal portion that comprises a gate pad, and the one or more lumped gate resistors are interposed on an electrical path between the gate pad and at least some of the gate electrodes.

In some embodiments, the first doping concentration is at least an order of magnitude greater than the second doping concentration. In some embodiments, the first semiconductor material comprises polysilicon.

In some embodiments, the first dopant type is different from the second dopant type.

In some embodiments, the metal gate pad is electrically connected to the metal gate bus through the lumped gate resistor, and at least some of the gate electrodes are electrically connected to the lumped gate resistor through the metal gate bus.

In some embodiments, the gate structure has a gate resistance that varies by less than 6% per 100° C. over an operating temperature range of the semiconductor device.

In some embodiments, the semiconductor layer structure comprises at least one wide bandgap semiconductor layer.

Pursuant to still additional embodiments of the present invention, semiconductor devices are provided that comprise a semiconductor layer structure and a gate structure on the semiconductor layer structure. The gate structure comprises a first section that has a positive resistance temperature coefficient and a second section that has a negative resistance temperature coefficient

In some embodiments, the first section of the gate structure comprises a plurality of gate electrodes that are on an active region of the semiconductor layer structure and the second section of the gate structure comprises a lumped gate resistor. In some embodiments, the gate structure further comprises a metal portion that comprises a gate pad, and the lumped gate resistor is interposed on an electrical path between the gate pad and at least some of the gate electrodes.

In some embodiments, the first section of the gate structure comprises doped polysilicon and the second section of the gate structure comprises silicon-chromium.

Pursuant to still other embodiments of the present invention, semiconductor devices are provided that comprise a semiconductor layer structure and a gate structure on the semiconductor layer structure, the gate structure including a plurality of polysilicon gate electrodes. The gate structure has a gate resistance that varies by less than 6% per 100° C.

In some embodiments, gate structure comprises a high resistance portion and a low-resistance portion, and a first section of the high resistance portion of the gate structure has a first resistance temperature coefficient and a second section of the high resistance portion of the gate structure has a second resistance temperature coefficient that is at least 25% less than the first resistance temperature coefficient. In some embodiments, the first section of the high resistance portion of the gate structure comprises the plurality of gate electrodes and the second section of the high resistance portion of the gate structure comprises a lumped gate resistor. In some embodiments, the gate structure further comprises a metal portion that comprises a gate pad, and the lumped gate resistor is interposed on an electrical path between the gate pad and at least some of the gate electrodes.

In some embodiments, the first section of the high resistance portion of the gate structure comprises a first material and the second section of the high resistance portion of the gate structure comprises a second material that is different from the first material. In some embodiments, the first material is doped polysilicon and the second material comprises silicon-chromium.

In some embodiments, the first section of the high resistance portion of the gate structure comprises a first semiconductor material that has a first doping concentration and the second section of the high resistance portion of the gate structure comprises the first semiconductor material that has a second doping concentration that is less than the first doping concentration. In some embodiments, the first semiconductor material comprises polysilicon.

In some embodiments, the first section of the high resistance portion of the gate structure comprises a first semiconductor material that is doped with a first dopant type and the second section of the high resistance portion of the gate structure comprises the first semiconductor material that is doped with a second dopant type.

In some embodiments, the first section of the high resistance portion of the gate structure has a positive resistance temperature coefficient and the second section of the high resistance portion of the gate structure has a negative resistance temperature coefficient.

### BRIEF DESCRIPTION OF DRAWINGS

FIG. 1A is a schematic plan view of a power MOSFET according to embodiments of the present invention.

FIG. 1B is a schematic side view of the power MOSFET of FIG. 1A.

FIG. 2A is a schematic plan view of the power MOSFET of FIGS. 1A-1B with the upper dielectric layers removed.

FIG. 2B is a schematic plan view of the power MOSFET of FIGS. 1A-1B with the upper dielectric layers and the source metallization removed.

FIG. 2C is a schematic cross-section taken along line 2C-2C of FIG. 2B with the source metallization included for context.

FIG. 3A is an enlarged plan view of the region labeled “3A” of FIG. 2B with the metal source contact and various dielectric layers omitted to show the components of the gate structure.

FIG. 3B is a schematic cross-section taken along line 3B-3B of FIG. 3A.

FIG. 3C is another enlarged plan view of the region labeled “3A” of FIG. 2B with the metal gate pad and metal gate bus omitted to reveal the lumped gate resistors that are interposed on the electrical path between the metal gate pad and the metal gate bus.

FIGS. 3D and 3E are cross-sectional views taken along lines 3D-3D and 3E-3E, respectively, of FIG. 3C that illustrate how the gate current is forced to flow through the lumped gate resistors.

FIG. 4 is a graph illustrating the variation in total gate resistance as a function of temperature for a power semiconductor device having a conventional design as compared to two power semiconductor devices according to embodiments of the present invention.

FIG. 5 is a schematic cross-sectional view of a power MOSFET according to further embodiments of the present invention

FIG. 6 is a schematic plan view of a power MOSFET according to still further embodiments of the present invention.

FIGS. 7A and 7B are schematic cross-sections of two different versions of the power MOSFET of FIG. 6 that are taken along line 7A/B-7A/B of FIG. 6.

FIG. 8 is a schematic plan view of a power MOSFET according to yet additional embodiments of the present invention.

FIG. 9 is a schematic cross-sectional view of a trench gate power semiconductor device according to embodiments of the present invention.

### DETAILED DESCRIPTION

As discussed above, power semiconductor devices such as MOSFETs, IGBTs, gate-controlled thyristors and the like may include lumped gate resistors that are designed to increase the gate resistance to desired values to effectively slow down the individual device switching characteristics so that all devices in a circuit switch at the appropriate time and so that transient switching overshoots are reduced. In many cases, these lumped gate resistors are formed as one or more polysilicon regions in the semiconductor device that are interposed on the electrical path between a metal gate pad and a metal gate bus. The gate signal must pass through these polysilicon regions to pass from the metal gate pad to the metal gate bus, and the size and shape of the polysilicon regions may be configured to provide a desired amount of resistance. Generally speaking, the performance of the semiconductor device may vary significantly with the amount of gate resistance, and hence power semiconductor devices are typically designed to keep the gate resistance very close to a desired value, as even small variations from an ideal resistance value can negatively affect the performance of the power semiconductor device.

Unfortunately, the resistance of the materials that are typically used to form gate resistors may vary with temperature. The resistance may vary based on the type of material and, for semiconductor materials, the doping density and/or the type of dopant used to dope the semiconductor material. For example, degenerately-doped (i.e., very highly doped) polycrystalline silicon (“polysilicon”) has a resistance temperature coefficient of, for example, between +6.5×10⁻⁴/° C. and 9×10⁴/° C. (i.e., for each increase in temperature of 1° C., the resistance of degenerately-doped polysilicon increases by 0.065% to 0.09%). While this rate of change is relatively small, the operating temperature of gate-controlled power semiconductor devices may vary from, for example, room temperature (25° C.) to 175° C. or more. Thus, assuming an operating temperature range of 150° C., the resistance of degenerately-doped polysilicon may vary by 12%. This amount of change may be large enough to negatively affect the performance of various power semiconductor devices.

Pursuant to embodiments of the present invention, gate-controlled power semiconductor devices are provided that have temperature compensated gate resistances that exhibit reduced resistance variation with changes in temperature. This may be accomplished by forming different portions of the total gate resistance using materials that have different resistance temperature coefficients. For example, as discussed above, degenerately-doped polysilicon may roughly have a resistance temperature coefficient of between +6.5×10⁴/° C. and 9×10⁻⁴/° C., which is referred to as a “positive” resistance temperature coefficient since the resistance increases with increasing temperature. If, for example, a power semiconductor device that has a gate structure that is formed of metal and degenerately-doped polysilicon was modified to have lumped gate resistors that are formed of a material that has a lower positive resistance temperature coefficient, a resistance temperature coefficient of zero, or a negative resistance temperature coefficient, then the resistance temperature coefficient of the total gate resistance would be reduced. This may improve device performance.

As noted above, the gate structures of most gate-controlled power semiconductor devices include both metal portions and portions that include semiconductor materials. For example, the gate pad and the gate bus are typically formed of metal, while the gate electrodes and any lumped gate resistors are typically formed of a semiconductor material such as polysilicon. The sheet resistance of the metal is typically many orders of magnitude less (e.g., four orders of magnitude or more less) than the sheet resistance of highly doped semiconductor materials such as polysilicon, and the percentage of the gate structure that is formed of metal is typically less than the percentage of the gate structure that is formed of a semiconductor material. As such, the metal components of a conventional gate structure typically account for a very small percentage of the total gate resistance (e.g., less than 0.01%) and have no discernible impact on the total gate resistance.

In some embodiments of the present invention, power semiconductor devices are provided that include gate structures formed using a combination of semiconductor materials and metal, where the same semiconductor material is used throughout the gate structure, but different portions of the semiconductor material used in the gate structure are doped to different doping levels and/or doped using different dopant types so that different portions of the semiconductor-based segments of the gate structure have different resistance temperature coefficients. In these embodiments, the power semiconductor devices may, for example, have lumped gate resistor(s) that are formed of a different material than the gate electrodes. In other cases, at least a portion of the gate bus is formed of a different material than the gate electrodes. In each case, the portions of the semiconductor material that are doped differently may have different resistance temperature coefficients. For example, in the above embodiments, the lumped gate resistor(s) or the portion of the gate bus may be formed of SiCr while the gate electrodes may be formed of polysilicon. SiCr may be designed to have a resistance temperature coefficient of zero or to even have a negative resistance temperature coefficient. This may help to reduce the overall variation in resistance across the operating temperature range of the power semiconductor device.

In all of the above-described embodiments, the materials used to form the gate structures and the proportions that each material form of the gate structures may be selected to, among other things, reduce the overall resistance temperature coefficient of the gate structure.

Example embodiments of the present invention will now be described in greater detail with reference to the attached figures. It will be appreciated that the embodiments shown in the figures are merely examples of representative embodiments, and thus the scope of the present invention is in no way limited by the example embodiments shown in the figures and discussed below. Instead, the scope of the present invention is defined by the appended claims.

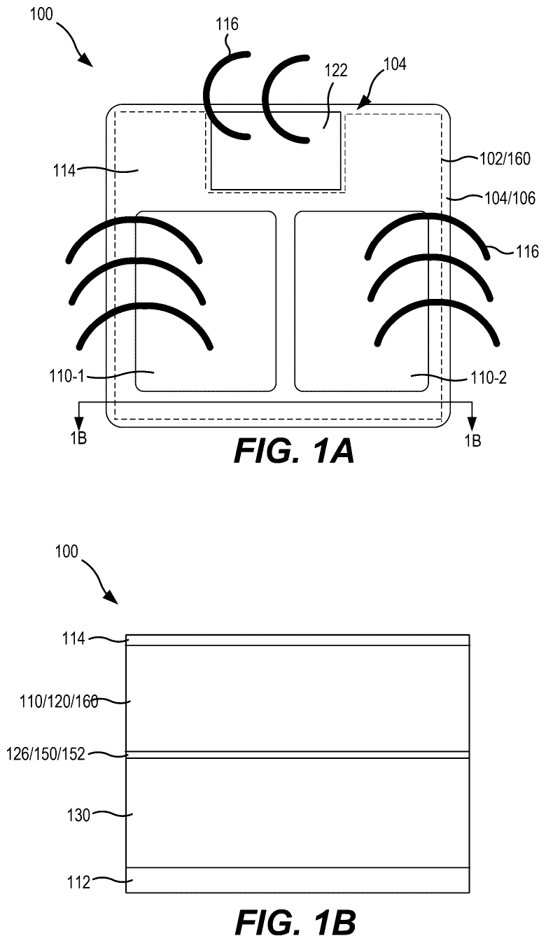

FIGS. 1A-1B schematically illustrate a gate-controlled power semiconductor device 100 according to certain embodiments of the present invention, where the semiconductor device 100 is a power MOSFET as an example. In particular, FIG. 1A is a schematic plan view of the power MOSFET 100, and FIG. 1B is a schematic cross-sectional view of the power MOSFET 100 that illustrates (at a high level) the primary semiconductor, metal and dielectric regions of the power MOSFET 100.

Referring to FIGS. 1A and 1B, it can be seen that power MOSFET 100 includes a semiconductor layer structure 130 and metal and dielectric layers that are formed on either side of the semiconductor layer structure 130. As shown in FIGS. 1A-1B, a gate pad 122 and one or more source pads 110-1, 110-2 are formed on the upper side of the semiconductor layer structure 130. Bond wires 116 are shown in FIG. 1A that may be used to connect the gate pad 122 and the source pads 110-1, 110-2 to external circuits or the like. Each of the gate and source pads 122, 110 may be formed of a metal, such as aluminum, that the bond wires 116 can be readily attached to via conventional techniques such as thermo-compression or soldering. A protective layer 114 such as a polyimide layer may cover the entire upper surface of power MOSFET 100 except for the gate and source pads 122, 110.

The power MOSFET 100 includes a metal source contact 160 that electrically connects certain regions of the semiconductor layer structure 130 to the source pads 110-1, 110-2. The metal source contact 160 is indicated by a dashed box in FIG. 1A. The source pads 110-1, 110-2 may be portions of the metal source contact 160 that are exposed through openings in the protective layer 114 or may be separate metal layers. The metal source contact 160 may generally overlie or correspond to an “active region” 102 of the power MOSFET 100 where the unit cell transistors are located. An inactive region 104 of power MOSFET 100 surrounds the active region 102. The inactive region 104 may include a termination region 106 that extends around the periphery of the MOSFET 100 that includes guard rings, junction termination elements or other termination structures (not shown), a gate pad region that underlies the gate pad 122, and gate bus regions that underlie the gate buses (discussed below).

As shown in FIG. 1B, a drain pad 112 is provided on the bottom side of the semiconductor layer structure 130. The drain pad 112 may be formed of a metal that may be connected to an underlying submount (not shown) such as a lead frame, a heat sink, a power substrate or the like via soldering, brazing, direct compression or the like. The drain pad 112 may be connected to an external circuit through the submount (not shown) on which power MOSFET 100 is mounted. A gate structure 120 (that includes the metal gate pad 122), the metal source contact 160 and the source pads 110 are formed on and/or in the upper surface of the semiconductor layer structure 130. In many cases a single metal layer is used to form both the metal portions of the gate structure 120 and the metal source contact 160. Dielectric layers are provided that insulate the gate structure 120 from the metal source contact 160. A protective layer (e.g., the above-discussed polymide layer 114) is formed on top of the gate structure 120 and the metal source contact 160, with openings in the protective layer 114 exposing the gate pad 122 and the exposed upper portion of the metal source contact 160 forming the source pads 110.

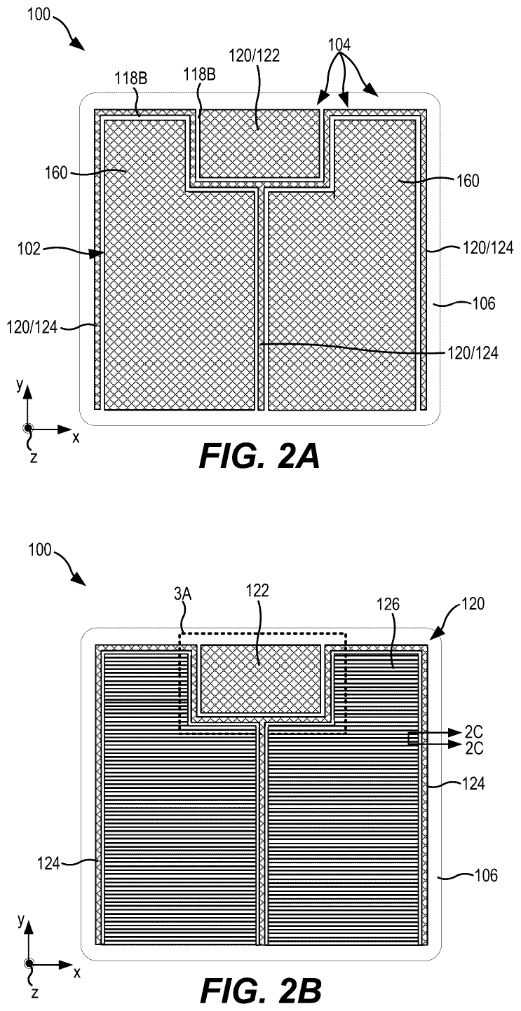

FIG. 2A is a schematic plan view of the power MOSFET 100 of FIGS. 1A-1B with the upper dielectric layers (e.g., the polymide layer 114) removed to better illustrate the gate and source metallization.

As shown in FIG. 2A, the gate structure 120 includes, among other things, the metal gate pad 122 as well as a metal gate bus 124. The metal gate pad 122 is separated from the gate bus 124 by an intermetal dielectric layer 118B. The metal gate bus 124 may, as shown, extend around much of the periphery active region 102 of power MOSFET 100. Gate signals that are input to the metal gate pad 122 are passed to the metal gate bus 124 in a manner that will be discussed in greater detail below. The metal gate bus 124 provides a low resistance path for passing the gate signal to gate electrodes 126 (see FIG. 2B and discussion below) that extend throughout the active region 102. A gap 117 (which may be partially or completely filled by the polyimide layer 114) separates the gate bus 124 from the source pads 110-1, 110-2 to prevent any short circuit between the gate and source of power MOSFET 100. As shown in FIG. 2A, the gate pad 122 and the gate bus 124 do not overlap each other in the vertical direction (i.e., they do not “vertically overlap,” meaning that no axis that extends along the z-direction passes through both the gate bus 124 and the gate pad 122), and the gate pad 122 and the gate bus 124 also do not vertically overlap the source pads 110. As such, a single metal layer may be used to form the gate pad 122, the gate bus 124 and the source pads 110-1, 110-2.

In FIG. 2A, the active region 102 may exactly or almost exactly correspond to the regions of the semiconductor layer structure 130 of power MOSFET 100 that are covered by the metal source contact 160. The inactive region 104 includes the portions of the semiconductor layer structure 130 that are underneath the gate pad 122 and the gate bus 124, as well as a termination region 106 that extends around the periphery of the power MOSFET 100.

FIG. 2B is a schematic plan view of the power MOSFET 100 of FIGS. 1A-1B with the upper dielectric layers and the source metallization (i.e., the metal source contact 160 and the source pads 110-1, 110-2) removed. In other words, FIG. 2B corresponds to the view of FIG. 2A with the intermetal dielectric layer 118B, the source pads 110-1, 110-2 and the underlying metal source contact 160 removed to better illustrate the gate structure 120 of power MOSFET 100. As noted above, a single metal layer is often used to form the metal gate pad 122, the metal gate bus 124, and the source metallization 160, 110. In FIG. 2B, the portion of this single metal layer that forms the source metallization 160, 110 is omitted as is the portions of the intermetal dielectric layers 118A, 118B that are in the active region so that the gate electrodes are visible in the figure.

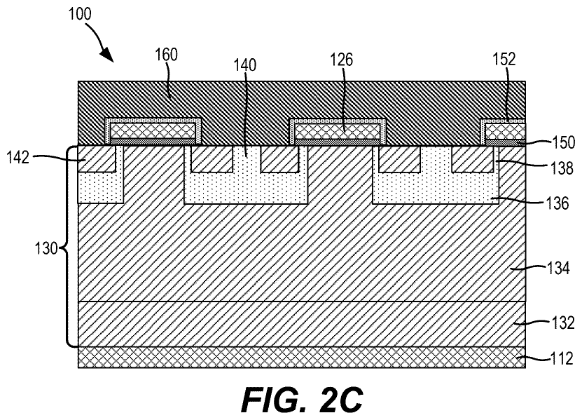

As shown in FIG. 2B, the gate structure 120 comprises the gate pad 122, the gate bus 124 and a plurality of gate electrodes 126 (also referred to herein as gate fingers 126). Typically, the gate pad 122 and the gate bus 124 are formed of metal, while the gate electrodes 126 are formed of a semiconductor material (typically polysilicon). A conductive pattern 170 (see FIG. 3B) that is typically formed of polysilicon is provided between the semiconductor layer structure 130 and the gate bus 124. The polysilicon pattern 170 is also part of the gate structure 120. The polysilicon pattern 170 may electrically connect the gate bus 124 to ends of the individual gate electrodes 126.

The gate electrodes 126 may extend horizontally across the device (as shown in FIG. 2B), or may have other configurations such as a mesh structure where the gate electrodes 126 extend both horizontally and vertically, or may have a so-called “unit cell” configuration where the gate electrode is a continuous layer and a plurality of hexagonal (or other shaped) openings are formed in the gate electrode to expose the source regions and the well contact regions, as is known in the art.

FIG. 2C is a schematic cross-section taken along line 2C-2C of FIG. 2B with the metal source contact 160 added in FIG. 2C for context. FIG. 2C illustrates one full unit cell transistor and portions of two additional unit cells of power MOSFET 100.

As shown in FIG. 2C, the drain pad 112 is formed on the lower side of the semiconductor layer structure 130. The drain pad 112 may form an ohmic contact to the semiconductor layer structure 130 and may act as the drain terminal of power MOSFET 100. The drain pad 112 may comprise, for example, metals such as nickel, titanium, tungsten and/or aluminum, and/or silicides and/or alloys and/or thin layered stacks of these and/or similar materials.

As is further shown in FIG. 2C, the semiconductor layer structure 130 may comprise a substrate 132. In some embodiments, the semiconductor substrate 132 may comprise an n-type silicon carbide semiconductor substrate 132 such as, for example, a single crystal 4H silicon carbide semiconductor substrate. The semiconductor substrate 132 may be heavily-doped (e.g., between 1×10¹⁸ atoms/cm³ and 1×10²¹ atoms/cm³) with n-type impurities, although other substrates may be used. The substrate 132 may have any appropriate thickness (e.g., between 50 and 500 microns thick), and may be partially or fully removed in some embodiments. It will be appreciated that the thickness of the substrate 132 and other layers are not drawn to scale in FIG. 2C or the other figures.

A plurality of semiconductor layers may be formed on the substrate 132, typically by epitaxial growth. These semiconductor layers may include a lightly-doped n-type (n⁻) silicon carbide drift region 134 that is provided on an upper surface of the substrate 132. The n-type silicon carbide drift region 134 may have, for example, a doping concentration of 1×10¹⁴ to 5×10¹⁶ dopants/cm³. The n-type silicon carbide drift region 134 may be a thick region, having a vertical height above the substrate 132 of, for example, 3-100 microns. While not shown in FIG. 2C, in some embodiments an upper portion of the n-type silicon carbide drift region 134 may be more heavily doped (e.g., a doping concentration of 1×10¹⁶ to 1×10¹⁷ dopants/cm³) than the lower portion thereof to provide a current spreading layer in the upper portion of the n-type silicon carbide drift region 134.

P-type well regions 136 are formed in upper portions of the n-type drift region 134. A pair of heavily-doped (n⁺) n-type silicon carbide source regions 142 may then be formed in upper portions of each well region 136 by, for example, ion implantation. Channel regions 138 are defined in the sides of the well regions 136. In addition, the portion of each p-well 136 that is between the source regions 142 may be more heavily doped than, for example, the channel regions (and perhaps the rest of the well region 136) to provide a well contact region 140 in each well region 136. The substrate 132, the drift region 134, the well regions 136, the well contact regions 140, and the source regions 142 may together comprise the semiconductor layer structure 130 of power MOSFET 100. The semiconductor layer structure 130 may be a wide bandgap semiconductor layer structure 130 (i.e., a semiconductor layer structure 130 that includes wide bandgap semiconductor materials).

A plurality of gate dielectric layers 150 are formed on the upper surface of the semiconductor layer structure 130. The gate dielectric layers 150 are typically formed as thin silicon oxide layers. The gate electrodes 126 are formed on the respective gate dielectric layers 150 so that a respective gate dielectric layer 150 is interposed between each gate electrode 126 and the semiconductor layer structure 130. Respective intermetal dielectric layers 152 cover the upper and side surfaces of the gate electrodes 126. A metal source contact 160 is formed over the active region 102 of the device to cover the gate electrodes 126. The source contact 160 may directly contact the source regions 142 and well contact regions 140 of the semiconductor layer structure 130. The intermetal dielectric layers 152 electrically isolate the source contact 160 from the gate electrodes 126. The source contact 160 may include one or more layers such as, for example, a diffusion barrier layer and a bulk metal layer.

Channel regions 138 are provided in each well region 136. The channel regions 138 electrically connect the n-type source regions 142 to the drift region 134 when a sufficient bias voltage is applied to the gate electrodes 126. When the bias voltage is applied to the gate electrodes 126, current may flow from the n-type source regions 142 through the channel regions 138 to the drift region 134 and then to the drain pad 112.

As discussed above, gate-controlled power semiconductor devices such as power MOSFET 100 often include lumped gate resistors 174 (see FIGS. 3B and 3D) within the gate structure 120 (see FIGS. 2A-2B) that increase the gate resistance to, for example, limit the switching speed of the device or reduce electrical ringing. These lumped gate resistors 174 are most typically interposed on the electrical path between the gate pad 122 and the gate bus 124. FIGS. 3A-3E illustrate how one or more lumped gate resistors 174 are implemented in power MOSFET 100. In particular, FIG. 3A is an enlarged plan view of the region labeled “3A” of

FIG. 2B, with the polyimide layer 114, the metal source contact 160 and portions of the intermetal dielectric layers 118A, 118B (discussed below) omitted so that the gate electrodes 126 and gate bus 124 are visible. FIG. 3B is a schematic cross-section taken along line 3B-3B of FIG. 3A. FIG. 3C is another enlarged plan view of the region labeled “3A” of FIG. 2B with the metal gate pad 122 and metal gate bus 124 and portions of the intermetal dielectric layer 118B omitted to reveal the lumped gate resistors 174 that are interposed on the electrical path between the metal gate pad 122 and the metal gate bus 124. FIGS. 3D and 3E are cross-sectional views taken along lines 3D-3D and 3E-3E, respectively, of FIG. 3C that illustrate how the gate current is forced to flow through the lumped gate resistors 174. FIG. 3D also is a greatly enlarged version of a small portion of FIG. 3B that corresponds to the box labelled “3D” in FIG. 3B.

Referring first to FIG. 3B, the metal gate pad 122 is primarily formed on an upper intermetal dielectric layer 118B. The upper intermetal dielectric layer 118B is formed on an underlying lower intermetal dielectric layer 118A, which in turn is formed on a field oxide layer 154 (e.g., a thick silicon oxide layer) that is formed on the upper surface of the semiconductor layer structure 130 in the gate pad region of the power MOSFET 100. As will be discussed in greater detail below, two intermetal dielectric layers 118A, 118B are provided so that lumped gate resistors 174 are formed that are buried within a composite intermetal dielectric layer that is the combination of intermetal dielectric layers 118A, 118B. Gate oxide layers 150 are formed on the upper surface of the semiconductor layer structure 130 throughout the active region 102, and the polysilicon gate electrodes 126 are formed on the gate oxide layers 150. The gate oxide layers 150 insulate the gate electrodes 126 from the semiconductor layer structure 130. The conductive pattern 170 is formed on the field oxide layer 154. As the conductive pattern 170 is a polysilicon pattern 170 in this particular embodiment, it will be referred to as a polysilicon pattern 170 in the remainder of the description of power MOSFET 100. It will be appreciated, however, that the conductive pattern 170 may comprise materials other than polysilicon in other embodiments. The polysilicon pattern 170 may be formed underneath the segments of the metal gate bus 124 and underneath both intermetal dielectric layers 118A, 118B, as shown. One or more vias are provided that extend through the intermetal dielectric layers 118A, 118B so that the gate bus 124 may include downward protrusions that directly contact the polysilicon pattern 170. Gate signals that are travelling along the gate bus 124 pass through the downward protrusions to enter the polysilicon pattern 170 and then pass from the polysilicon pattern 170 into the individual gate fingers 126.

A conductive pattern 172 is formed on the lower intermetal dielectric layer 118A near the polysilicon pattern 170. In the depicted embodiment, the conductive pattern 172 is formed at a higher level in the device than the polysilicon pattern 170, with a first end of the conductive pattern 172 being below the metal gate pad 122 and a second end of the conductive pattern 172 being below the metal gate bus 124. The conductive pattern 172 may have the same thickness as the polysilicon pattern 170 (as shown) or may have a different thickness. The metal gate pad 122 and the metal gate bus 124 may each have downward protrusions that contact respective ends of the conductive pattern 172. As shown, the conductive pattern 172 provides a path that electrically connects the metal gate pad 122 to the metal gate bus 124.

The metal gate bus 124 is electrically connected to the individual gate electrodes 126 through the polysilicon pattern 170. As shown in both FIGS. 3A and 3B, gaps 117 are interposed in between the metal gate pad 122 and the metal gate bus 124 and in between the metal gate bus 124 and the metal source contacts 160 (note that in this embodiment the source pads 110 are just an exposed upper surface of the metal source contact 160). These gaps 117 ensure that direct electrical connections are not provided between the metal gate pad 122 and the metal gate bus 124 or between the metal gate bus 124 and the source contact 160. A passivation layer (not shown, but see polymide layer 114 of FIG. 1A) that is formed as a protective layer over the upper surface of power MOSFET 100 will typically at least partly fill the gaps 117.

FIG. 3C is a plan view of region 3A of power MOSFET 100 with the polymide layer 114, the gate pad 122, the gate bus 124, the metal source contact 160 and most of the lower and upper intermetal dielectric layers 118A, 118B omitted. The lower surface of the upper intermetal dielectric layer 118B includes downwardly-extending protrusions 119 that extend into openings in the conductive pattern 172. These downwardly-extending protrusions 119 of the intermetal dielectric layer 118B are shown in FIG. 3C. FIG. 3C thus corresponds to a horizontal cross-section taken along the line 3C-3C of FIG. 3B.

As discussed above with reference to FIG. 3B, the metal gate pad 122 and the metal gate bus 124 both directly contact the conductive pattern 172. As such, the conductive pattern 172 electrically connects the metal gate pad 122 to the metal gate bus 124. The downwardly-extending protrusions 119 of the intermetal dielectric layer 118B effectively replace portions of the conductive pattern 172 and hence a plurality of discrete narrowed regions are formed in the conductive pattern 172 between the downwardly-extending protrusions 119. Each narrowed region has a width W and a length L (where the length L is along the direction of current flow). As can be seen, the only possible current paths for the gate signal to flow from the metal gate pad 122 to the metal gate bus 124 are the narrowed regions since the gate current cannot flow through the downwardly-extending protrusions 119. Thus, the downwardly-extending protrusions 119 act to funnel the gate current through the narrowed regions in the conductive pattern 172, which have increased resistance. Since the narrowed regions in the conductive pattern 172 have increased resistance, they form discrete or “lumped” gate resistors 174. The resistance of each lumped gate resistor 174 is a function of the width W and length L thereof, with the resistance increasing as the width W is decreased and as the length L is increased. Thus, lumped gate resistors 174 may be used to increase the gate resistance of the power MOSFET 100 to a desired value, and the amount of resistance provided by the lumped gate resistors 174 may be set by, for example, changing the width W and/or length L of one or more of the gate resistors 174 and/or by changing the number of gate resistors 174.

As shown in FIGS. 3B and 3C, the conductive pattern 172 does not vertically overlap the polysilicon pattern 170 and thus a thin strip 118S of dielectric material is visible in the plan view of FIG. 3C in between the conductive pattern 172 and the polysilicon pattern 170. As shown in FIG. 3B (and can better be seen in the enlarged view of FIG. 3D), the metal gate bus 124 includes a first downwardly protruding portion that contacts the conductive pattern 172 and a second downwardly protruding portion that contacts the polysilicon pattern 170 so that the conductive pattern 172 is electrically connected to the polysilicon pattern 170 through the metal gate bus 124.

FIGS. 3D and 3E are cross-sectional views taken along lines 3D-3D and 3E-3E, respectively, of FIG. 3C that illustrate how the gate current is forced to flow through the lumped gate resistors 174. As noted above, FIG. 3D corresponds to an enlarged view of the box labelled “3D” in FIG. 3B. As shown in FIG. 3D, when a gate signal is applied to the gate pad 122, the gate signal (i.e., a gate current) flows downwardly through the metal gate pad 122 and into the conductive pattern 172 since the metal gate pad 122 directly contacts the conductive pattern 172. Since the resistance of the metal gate pad 122 is orders of magnitude less than the resistance of the conductive pattern 172, the gate current will primarily enter the conductive pattern 172 in the location shown in FIG. 3D.

The gate current that is injected from the gate pad 122 into the conductive pattern 172 then flows laterally through the conductive pattern 172. As shown, the gate current will primarily flow in the upper portion of the conductive pattern 172 to minimize the path length for the current flow through the conductive pattern 172, although the gate current will spread to a degree throughout the conductive pattern 172. As soon as the gate current reaches the interface between the conductive pattern 172 and the metal gate bus 124, the gate current will almost all flow into the metal gate bus 124 as the resistance of the metal gate bus 124 is orders of magnitude less than the resistance of the conductive pattern 172. The gate current then flows through the gate bus 124 and into the polysilicon gate electrodes 126 along the “current path” shown in FIG. 3D.

The portion of the conductive pattern 172 shown in FIG. 3D corresponds to one of the lumped gate resistors 174 shown in the plan view of FIG. 3C. As can best be seen with reference to FIGS. 3A, 3C and 3D, the lumped gate resistors 174 are the only possible current path between the metal gate pad 122 and the metal gate bus 124. Thus, a gate current that is injected into the metal gate pad 122 must flow through the lumped gate resistors 174 to get to the metal gate bus 124. Since the resistance of the conductive pattern 172 is orders of magnitude greater than the resistances of the metal gate pad 122 and the metal gate bus 124, the narrowed regions in the conductive pattern 172 form lumped gate resistors 174.

Referring to FIG. 3E, it can be seen that the conductive pattern 172 includes gaps that are filled by the intermetal dielectric layer 118B (i.e., by the above-discussed downwardly-extending protrusions 119). The protrusions 119 thus form breaks in the conductive pattern 172 and prevent the gate current from flowing from the metal gate pad 122 to the metal gate bus 124 in the locations where the protrusions 119 are present. The amount of gate resistance added by the lumped gate resistors 174 may be adjusted by changing the length, width and/or number of protrusions 119, since this impacts the length, width and/or number of gate resistors 174. Generally speaking, increasing the length, decreasing the width and/or increasing the number of protrusions 119 acts to increase the total gate resistance.

Purchasers of power semiconductor devices often specify very tight ranges for the cumulative gate resistance of a power semiconductor device such as a power MOSFET. For example, a customer may specify a gate resistance value along with a tolerance of +/−5%, or even less. These tight tolerances may be required because the cumulative gate resistance may directly affect the switching speed of the device, and if the device does not exhibit the appropriate switching speed for the application in which it is used, oscillations or other undesired behavior may arise that can negatively affect system performance.

As discussed above, the total gate resistance of a power semiconductor device may vary with the operating temperature of the device since polysilicon (which is the material that is most commonly used to form gate resistors in power semiconductor devices) has a non-zero resistance temperature coefficient. While the resistance temperature coefficient of degenerately-doped polysilicon is small (typically within a range of about 6.5×10⁻⁴/° C. to 9×10⁻⁴/° C., meaning that for each increase in temperature of 1° C., the resistance increases by 0.065% to 0.09%, with the variation being a function of the grain structure dopant species choice, among other things), power semiconductor devices that are designed to block hundreds or thousands of volts may have operating temperature ranges that vary, for example, between room temperature (25° C.) and 175° C. or more. A temperature swing of, for example, 150° C., will result in a change in resistance of 12% in a gate structure formed of metal and polysilicon elements.

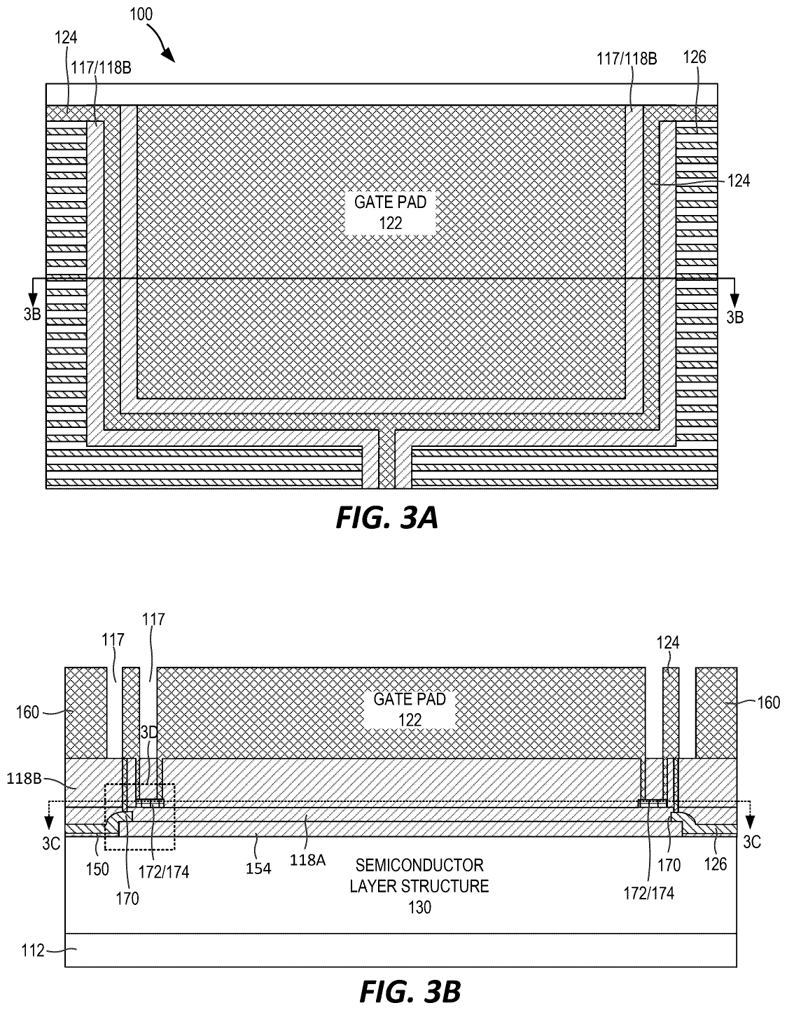

This can be seen with reference to FIG. 4, which is a graph showing how temperature variation can impact the total gate resistance of several power semiconductor devices. In FIG. 4, curve 180 illustrates the total gate resistance as a function of the temperature for a conventional power MOSFET that has a gate structure that is formed solely of metal and polysilicon structures. As shown, in this example, at room temperature the total gate resistance is 4 Ohms, and the total gate resistance increases linearly with increasing temperature to a value of 4.48 Ohms at a temperature of 175° C., which is an increase of 12%.

As discussed above, pursuant to embodiments of the present invention, semiconductor devices having gate structures that have lower temperature variation in the total gate resistance are provided. The power semiconductor device 100 of FIGS. 3A-3E is an example of one such embodiment. As described above, the reduced variation in the total gate resistance may be achieved by forming different portions of the gate structure 120 using materials that have different resistance temperature coefficients. For example, if the gate electrodes 126 of the power semiconductor MOSFET 100 are made of polysilicon (which has a resistance temperature coefficient of, for example, about +8×10⁻⁴/° C.), then one or more other portions of the gate structure 120 (e.g., the lumped gate resistors 174) may be formed of materials that have a lower resistance temperature coefficient (which could be a lower positive resistance temperature coefficient, a resistance temperature coefficient of zero, or a negative resistance temperature coefficient). Such a design acts to reduce the resistance temperature coefficient of the total gate resistance.

In power MOSFET 100 of FIGS. 3A-3E, the conductive pattern 172 is formed of a material that has, for example, a resistance temperature coefficient of −1×10⁴/° C. As such, the lumped gate resistors 174 are formed of a material having a resistance temperature coefficient of −1×10⁴/° C., and the remainder of the portions of the MOSFET 100 that have any material contribution to the total gate resistance (which is primarily the polysilicon gate electrodes 126) have a resistance temperature coefficient of +8×10⁴/° C. (since the metal elements along the gate current path have almost no contribution to the total gate resistance). Assuming, for example, that power MOSFET 100 has a total gate resistance of 4 Ohms at 25° C., with the gate resistors 174 comprising 2 Ohms of the gate resistance and the distributed polysilicon elements along the gate current path comprising the other 2 Ohms of the gate resistance, then curve 182 in FIG. 4 illustrates the total gate resistance as a function of temperature for the power MOSFET 100. As can be seen, in FIG. 4, the total gate resistance increases with temperature at less than half the rate of a comparable power MOSFET in which the lumped gate resistors were formed of polysilicon. As such, the total gate resistance only increases by slightly more than 5% over the 25-175° C. operating temperature range.

As is readily apparent, the variation in the total gate resistance with temperature may be further reduced by (1) using materials having more highly negative resistance temperature coefficients or (2) forming a greater percentage of the gate resistance using materials having more negative resistance temperature coefficients. Curve 184 in FIG. 4 illustrates the later technique. In particular, curve 184 shows the total gate resistance as a function of temperature for a power MOSFET having a total gate resistance of 4 Ohms where 1 Ohm of the total gate resistance is provided by polysilicon structures and 3 Ohms of the total gate resistance is provided by elements having a resistance temperature coefficient of −1×10⁴/° C. As shown, in this case, the variation in the total gate resistance over the 25-175° C. operating temperature range is less than 2.5%.

In some embodiments, the conductive pattern 172 (and hence the lumped gate resistors 174) may be formed of silicon-chromium (“SiCr”). SiCr may be designed to have a resistance temperature coefficient of zero or to even have a negative resistance temperature coefficient, and is stable over wide temperature ranges. Other materials that have reduced resistance temperature coefficients as compared to degenerately-doped polysilicon that could be used in gate structures of power semiconductor devices according to embodiments of the present invention include polysilicon with doping level reduced to provide a lower positive, zero, or negative temperature coefficient, and NiSi, CoSi, TiSi, WSi, TaSi or other silicide films with their composition designed to provide a lower positive, zero, or negative temperature coefficients. As is well-known for the silicide films, a more positive temperature coefficient is obtained as the metallic content is increased, and a more negative temperature coefficient is obtained as the silicon content is increased.

As discussed above, the gate structure 120 includes the metal gate pad 122, the metal gate bus 124, the polysilicon pattern 170 that underlies the metal gate bus 124 and the intermetal dielectric layers 118A, 118B, the conductive pattern 172 in which the lumped gate resistors 174 are formed, and the polysilicon gate fingers 126. The conductive pattern 172 may comprise silicon-chromium or another relatively high resistance material (i.e., high resistance as compared to metals such as aluminum or copper). The polysilicon pattern 170, the conductive pattern 172 and the polysilicon gate fingers 126 comprise a high resistance portion of the gate structure 120, while the metal gate pad 122 and the metal gate bus 124 comprise a low resistance portion of the gate structure 120. Herein, portions of the gate structure of a power semiconductor device according to embodiments of the present invention that have a sheet resistance of more than 10 ohms/square are considered to be part of the high resistance portion of the gate structure, while portions of the gate structure that have a sheet resistance of less than 100 milliohms/square are considered to be part of the low resistance portion of the gate structure. Portions of the gate structure (if provided) that have a sheet resistance between 100 milliohms/square and 10 ohms/square are considered to have an intermediate resistance.

Referring again to FIGS. 3A-3E, pursuant to some embodiments of the present invention, a power semiconductor device 100 is provided that comprises a semiconductor layer structure 130 and a gate structure 120 that comprises a high resistance portion and a low-resistance portion. The gate structure 120 is positioned on the semiconductor layer structure 130. The high resistance portion of the gate structure 120 comprises a first section (here the polysilicon gate electrodes 126) that has a first resistance temperature coefficient and a second section (here the SiCr lumped gate resistors 174) that has a second resistance temperature coefficient that differs from the first resistance temperature coefficient. The semiconductor layer structure 130 may comprise at least one wide bandgap semiconductor layer (e.g., silicon carbide layers 132, 134, 136, 138, 140, 142). In some embodiments, the power semiconductor device 100 may be or include a field effect transistor (e.g., a MOSFET).

In some embodiments, the second resistance temperature coefficient may be at least 25% less than the first resistance temperature coefficient (e.g., if the first resistance temperature coefficient is +800×10⁴/° C., then the second resistance temperature coefficient may be +600×10⁻⁴/° C. or less). In some embodiments, the first section of the high resistance portion of the gate structure 120 may include the gate electrodes 126 that are on the active region 102 of the semiconductor layer structure 130 and the second section of the high resistance portion of the gate structure 120 may include one or more of the lumped gate resistors 174. In some embodiments, the gate structure 120 may further comprise a metal portion that comprises a metal gate pad 122, and the lumped gate resistor(s) 174 are interposed on an electrical path between the metal gate pad 122 and at least some of the gate electrodes 126.

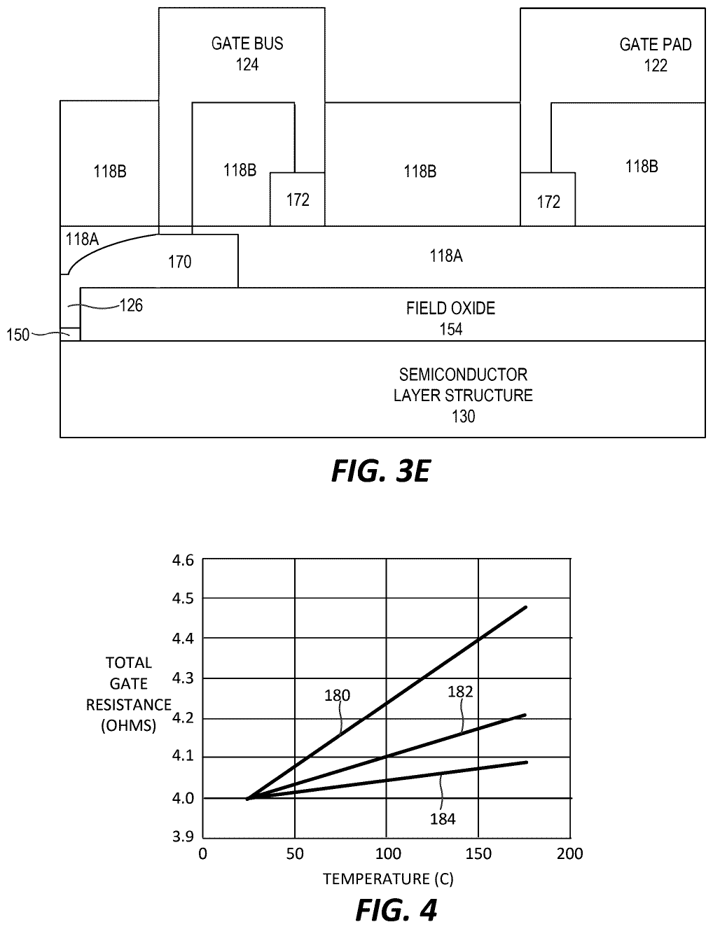

In some embodiments, the first section of the high resistance portion of the gate structure 120 may comprise a first material and the second section of the high resistance portion of the gate structure 120 may comprise a second material that is different from the first material. For example, the first section of the high resistance portion of the gate structure 120 may comprise polysilicon (e.g., the polysilicon gate electrodes 126) and the second section of the high resistance portion of the gate structure 120 may comprise silicon-chromium (e.g., the silicon-chromium lumped gate resistors 174). As will be discussed below with reference to FIG. 6, in other embodiments, the first section of the high resistance portion of the gate structure 120 may comprise a semiconductor material (e.g., polysilicon) that has a first doping concentration of a first dopant and the second section of the high resistance portion of the gate structure 120 may comprise the same semiconductor material that has a second doping concentration that is different than the first doping concentration and/or is doped with second dopants that are different than the first dopants.

In some embodiments, the first section of the high resistance portion of the gate structure 120 may comprise at least 10% (or at least 20% or at least 30%) of a total sheet resistance of the gate structure 120 and the second section of the high resistance portion of the gate structure 120 may comprise at least 10% (or at least 20% or at least 30%) of the total sheet resistance of the gate structure 120. In some embodiments, the first section of the high resistance portion of the gate structure 120 may have a positive resistance temperature coefficient and the second section of the high resistance portion of the gate structure 120 may have a negative resistance temperature coefficient. In other embodiments, the first section of the high resistance portion of the gate structure 120 may have a first positive resistance temperature coefficient and the second section of the high resistance portion of the gate structure 120 may have a second positive resistance temperature coefficient that is less than half the first resistance temperature coefficient. For example, the first positive resistance temperature coefficient is +8×10⁴/° C. and the second positive resistance temperature coefficient is greater than zero and less than +4×10⁻⁴/° C. In some embodiments, the gate structure 120 may have a gate resistance that varies by less than 6% per 100° C. over an operating temperature range of the power semiconductor device 100.

Still referring to FIGS. 3A-3E, pursuant to other embodiments of the present invention, a power semiconductor device 100 is provided that comprises a semiconductor layer structure 130 and a gate structure 120 on the semiconductor layer structure 130. The gate structure 120 includes a plurality of gate electrodes 126 and at least one lumped gate resistor 174. The gate electrodes 126 comprise a first material and the at least one lumped gate resistor 174 comprises a second material that is different from the first material.

Still referring to FIGS. 3A-3E, pursuant to yet additional embodiments of the present invention, a power semiconductor device 100 is provided that comprises a semiconductor layer structure 130 and a gate structure 120 on the semiconductor layer structure 130. The gate structure 120 comprises a first section (here the polysilicon gate electrodes 126) that has a positive resistance temperature coefficient and a second section that has a negative resistance temperature coefficient (here the silicon-chromium lumped gate resistors 174).

Still referring to FIGS. 3A-3E, pursuant to still other embodiments of the present invention, a power semiconductor device 100 is provided that comprises a semiconductor layer structure 130 and a gate structure 120 on the semiconductor layer structure 130, the gate structure 120 including a plurality of polysilicon gate electrodes 126. The gate structure has a gate resistance that varies by less than 6% per 100° C.

While FIGS. 3A-3E illustrate a power MOSFET 100 in which the lumped gate resistors 174 are formed of a different material than the distributed gate resistance, it will be appreciated that embodiments of the present invention are not limited thereto.

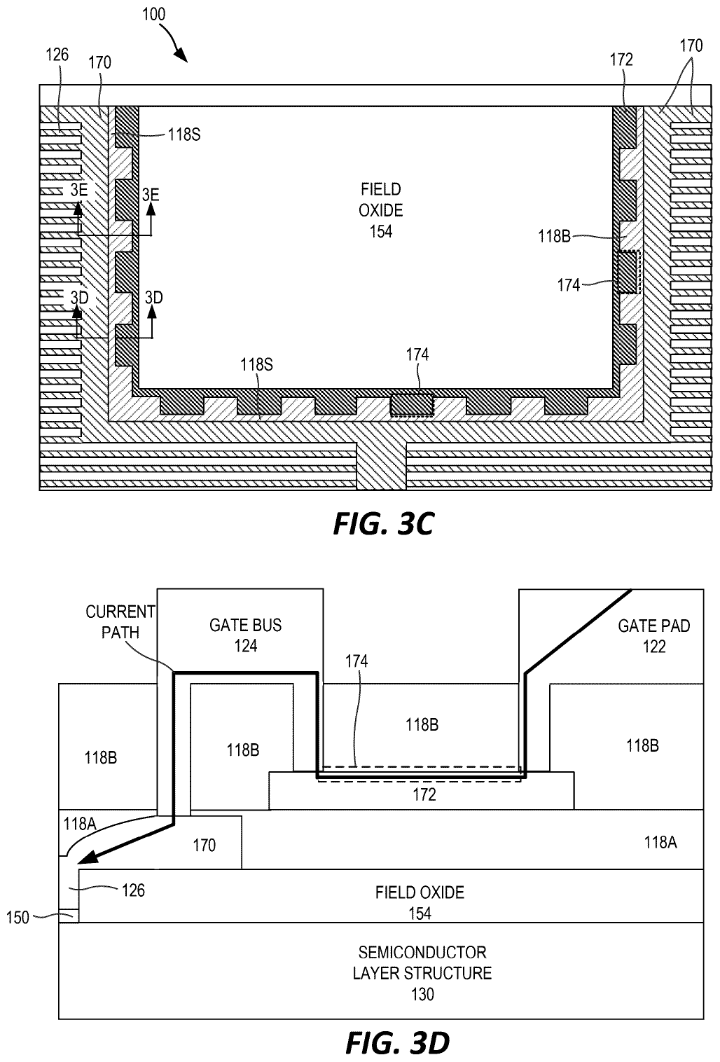

For example, FIG. 5 is a schematic cross-sectional view of a power MOSFET 200 according to further embodiments of the present invention. Power MOSFET 200 may be identical to power MOSFET 100, except that the silicon chromium pattern (or other pattern used to form lumped gate resistors) 272 is formed on an intermetal dielectric layer 118 directly in between the gate pad 122 and the metal gate bus 124.

FIG. 6 is a schematic plan view of a power MOSFET 300 according to further embodiments of the present invention. Power MOSFET 300 may be similar to power MOSFET 100, except that in power MOSFET 300, a conductive pattern 372 is provided in place of the SiCr conductive strips 172 of power MOSFET 100. The conductive pattern 372 may comprise polysilicon, and hence power MOSFET 300 may be similar to the design of most conventional silicon carbide-based power MOSFETs in that both the gate electrodes and the lumped gate resistors are formed using polysilicon. However, in power MOSFET 400, the doping concentration and/or the type of dopants used varies between the polysilicon gate electrodes 126 and the polysilicon pattern 372. As an example, the polysilicon pattern 372 may have a lower doping concentration than the polysilicon gate electrodes 126, and/or may be doped with dopants to form the lumped gate resistors 374 that have a lower resistance temperature coefficient than the polysilicon gate electrodes 126. The dopant concentrations and/or dopant types of the polysilicon pattern 372 (and hence the lumped gate resistors 374) versus the polysilicon gate electrodes 126 may be easily adjusted by doping the regions using different ion implantation steps. In some embodiments, the doped polysilicon gate electrodes 126 and the lumped gate resistors 374 may be formed in the same polysilicon layer. In other embodiments, the doped polysilicon gate electrodes 126 and the lumped gate resistors 374 may be formed in different polysilicon layers. The two polysilicon layers may or may not have the same thicknesses.

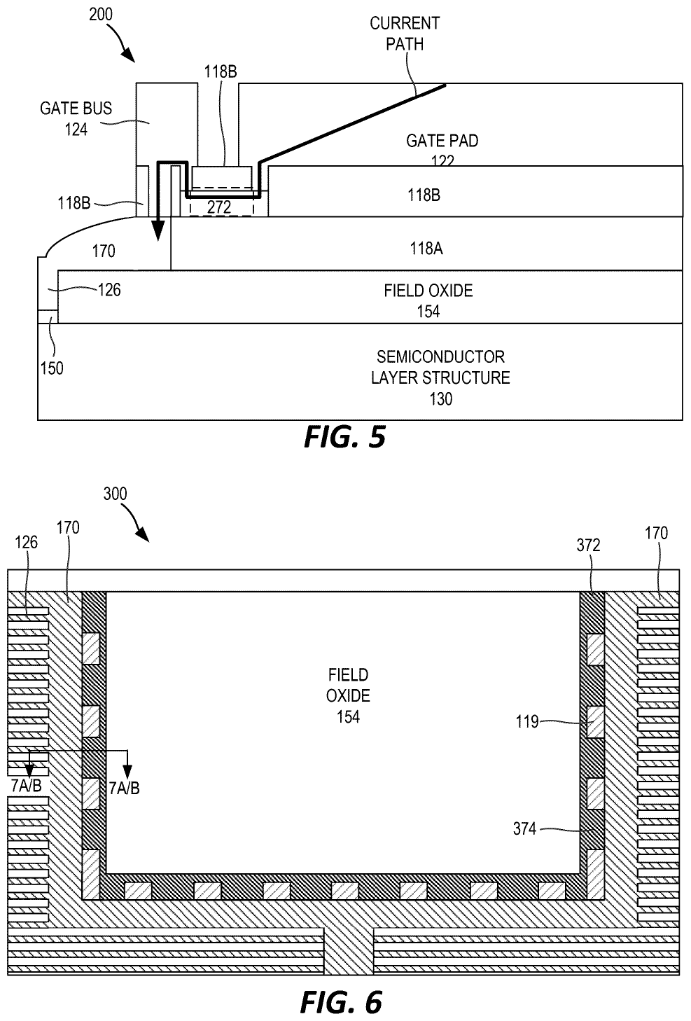

FIG. 7A is a cross-sectional view taken along line 7A/B-7A/B of FIG. 6 that illustrates the case where power MOSFET 300 has doped polysilicon gate electrodes 126 and lumped gate resistors 374 that are formed in the same polysilicon layer (this version of power MOSFET 300 is labeled as power MOSFET 300A in FIG. 7A). As shown in FIG. 7A, power MOSFET 300A may be very similar to power MOSFET 100 of FIGS. 3A-3E, with the primary differences being that (1) the SiCr pattern 172 of power MOSFET 100 is replaced with a polysilicon pattern 372 in power MOSFET 300 and (2) the doping concentration and/or the dopants included in the polysilicon pattern 170 and the gate electrodes 126 differ from the doping concentration and/or the dopants included in the polysilicon pattern 372, as can be seen by the different cross-hatching used in FIG. 7A.

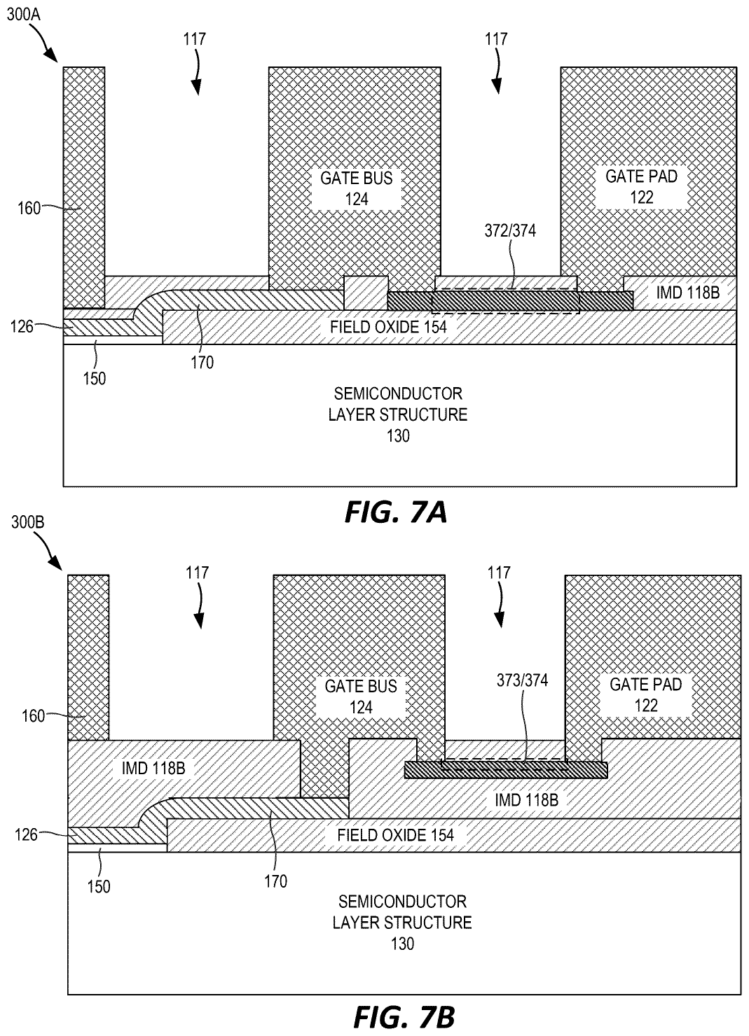

FIG. 7B is a cross-sectional view taken along line 7B-7B of FIG. 6 that illustrates the case where power MOSFET 300 has doped polysilicon gate electrodes 126 and doped polysilicon gate resistors 374 that are formed in different polysilicon layers (this version of power MOSFET 300 is labeled as power MOSFET 300B in FIG. 8B). As shown in FIG. 7B, power MOSFET 300B is very similar to power MOSFET 300A of FIG. 7A, but in power MOSFET 300B the polysilicon gate electrodes 126 and the polysilicon pattern 170 are formed in a first polysilicon layer and a second polysilicon pattern 373 is formed on the first polysilicon layer. The second polysilicon pattern 373 is formed in the portion of the device where the lumped gate resistors 374 are formed. The first polysilicon layer may have a first doping concentration and include a first dopant type and the second polysilicon pattern 373 may have a second doping concentration and include a second dopant type. The first doping concentration may be different from the second doping concentration and/or the first dopant type may be different from the second dopant type. In each of the above cases (including the example of FIG. 7A), the second polysilicon pattern may be more lightly doped than the first polysilicon pattern.

Referring to FIGS. 6 and 7A-7B, pursuant to still further embodiments of the present invention, a power semiconductor device 100 is provided that comprises a semiconductor layer structure 130 and a gate structure 120 that comprises a semiconductor portion on the semiconductor layer structure 130. The semiconductor portion of the gate structure 120 comprises a first section that comprises a first semiconductor material (e.g., polysilicon) and that has a first doping concentration and a second section that comprises the first semiconductor material and has a second doping concentration that is less than the first doping concentration.

FIG. 8 is a schematic plan view of a power MOSFET 400 according to further embodiments of the present invention. Power MOSFET 400 is similar to power MOSFET 300, except that power MOSFET 400 includes a polysilicon pattern 470 which has differently doped portions 472 that are adjacent the ends of each gate finger. The differently doped portions 472 have a resistance temperature coefficient that differs from the resistance temperature coefficient for the remainder of the polysilicon pattern 470.

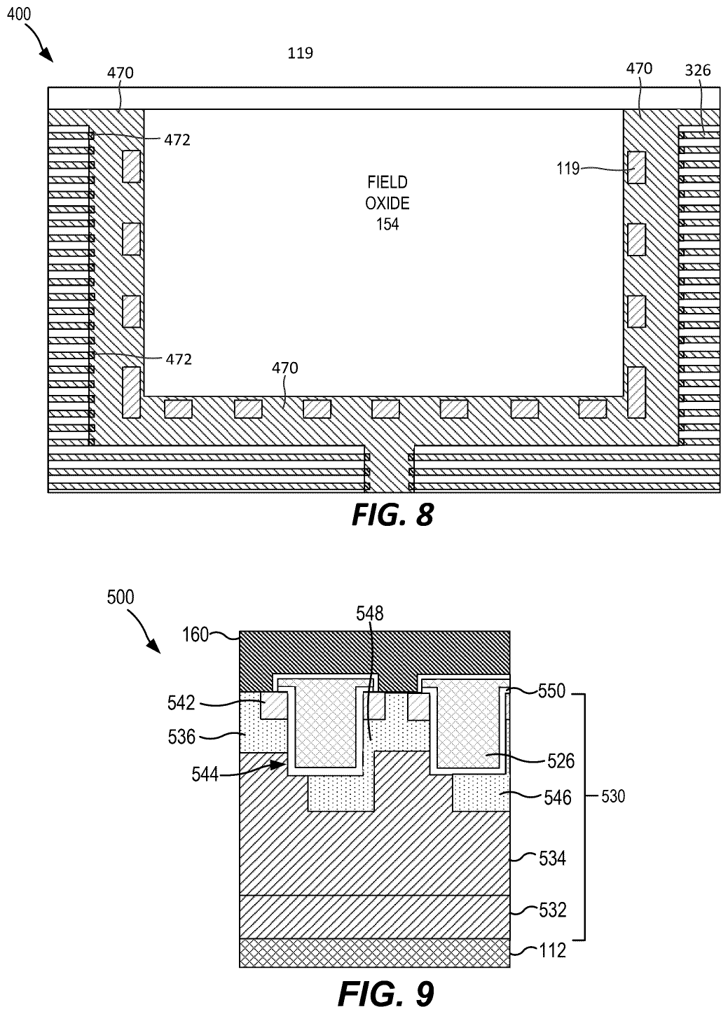

The above-described embodiments of the present invention are planar MOSFETs that have gate electrodes 126 that are formed on a semiconductor layer structure 130 that has a planar upper surface so that the bottom surfaces of the gate electrodes 126 are positioned above the upper surface of the semiconductor layer structure 130. It will be appreciated, however, that any of the above-discussed gate structure designs may be used in power MOSFETs that have gate electrodes that are fully or partially contained within trenches that are formed in the upper surface of the semiconductor layer structure. FIG. 9 is a schematic cross-section of a few unit cells of such a gate trench power MOSFET 500 (the cross-section of FIG. 9 generally corresponds to the cross-section of FIG. 2C). As shown in FIG. 9, the gate trench power MOSFET 500 includes a semiconductor layer structure 530 that comprises a heavily-doped n-type silicon carbide semiconductor substrate 532 and a lightly-doped n-type silicon carbide drift region 534 on the silicon carbide semiconductor substrate 532. A plurality of moderately doped p-type well regions 536 are formed in the upper surface of the drift region 534. Heavily-doped n-type source regions 542 are formed in upper portions of the p-type well regions 536. A plurality of longitudinally-extending gate trenches 544 (i.e., extending into the page in the view of FIG. 9) are formed in the upper surface of the semiconductor layer structure 530. The gate trenches 544 may extend in parallel to each other in example embodiments or may be in a mesh form where the gate trenches extend in rows and columns. Moderately or heavily-doped longitudinally-extending p-type trench shielding regions 546 are formed underneath the respective gate trenches 544. In addition, moderately or heavily-doped p-type trench shielding connection patterns 548 run in stripes across the device to electrically connect the trench shielding regions 546 to the p-type well regions 536. Gate electrodes 526 are formed in each gate trench 544, and a gate insulating layer 550 separates each gate electrode 526 from the semiconductor layer structure 530. A drain contact 112 is formed on the bottom of the semiconductor layer structure 530 and a source contact 160 is formed on the upper surface of the semiconductor layer structure 530. An intermetal dielectric pattern 552 isolates the source contact 116 from the gate electrodes 526.

It will be appreciated that each of the power MOSFETs discussed above that has non-trench gate electrodes may be modified to have gate electrodes that are formed within gate trenches (e.g., to have the design of FIG. 9 or any other gate trench MOSFET design).

In the discussion above, silicon chromium is used as one example of way of forming a portion of the gate structure that has a different resistance temperature coefficient that can be used to reduce the variation in the gate resistance as a function of temperature. It will be appreciated that a wide variety of other materials may be used in place of silicon chromium. For example a wide variety of different metal silicides could be used in other embodiments, including, for example, NiSi, TiSi, CoSi, Wsi and TaSi.

In the discussion above, references are made to power semiconductor devices that have gate structures that have a gate resistance that varies by less than certain amounts. The distributed gate resistance of a power semiconductor device may be a resistor-capacitor (RC) network that can be simulated as the RC time constant for the gate voltage to reach to a certain value, say 70 to 80% of an externally applied gate voltage, in all branches of the RC network. In the above described embodiments, the RC network corresponds to the gate structure, but the true metal components of the gate structure (e.g., the metal gate pad and metal gate bus) may be ignored as they have almost zero contribution to the gate resistance. As such, the distributed gate resistance may, for example, simply be the gate fingers. The R is then calculated from the simulated RC time constant using the known capacitance of the structure (e.g., the capacitance across the parallel gate oxide layers). This portion of the gate resistance is often called the “distributed” gate resistance of the power MOSFET, since it is essentially an AC resistance that is distributed by the gate network. The “lumped” gate resistance is a DC resistance, since it is formed over thick oxide (like FOX) where the capacitance component is negligible.

It will be appreciated that while the discussion herein has focused on power MOSFET devices as examples, the techniques disclosed herein are not limited to such devices. For example, the techniques disclosed herein may also be used in IGBT devices, JFETs, thyristors, GTOs or any other gate-controlled power semiconductor device.

While the MOSFETs discussed above are n-type devices with the source bond pad on an upper side thereof and the drain pad on the bottom side thereof, it will be appreciated that in p-type devices these locations are reversed. Moreover, while the above-described power MOSFETs and the other devices described herein are shown as being silicon carbide-based semiconductor devices, it will be appreciated that embodiments of the present invention are not limited thereto. Instead, the semiconductor devices may comprise any wide bandgap semiconductor that is suitable for use in power semiconductor devices including, for example, gallium nitride-based semiconductor devices, gallium nitride-based semiconductor devices and II-VI compound semiconductor devices.

The power semiconductor devices according to embodiments of the present invention may exhibit lower variations in the total gate resistance as a function of temperature.

The invention has been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the invention are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device, comprising:
a semiconductor layer structure; and
a gate structure that comprises a high resistance portion and a low-resistance portion on the semiconductor layer structure,
wherein the high resistance portion of the gate structure comprises a first section that has a first resistance temperature coefficient and a second section that has a second resistance temperature coefficient that differs from the first resistance temperature coefficient.

2. The semiconductor device of claim 1, the second resistance temperature coefficient may be at least 25% less than the first resistance temperature coefficient.

3. The semiconductor device of claim 1, wherein the first section of the high resistance portion of the gate structure comprises a plurality of gate electrodes that are on an active region of the semiconductor layer structure and the second section of the high resistance portion of the gate structure comprises a lumped gate resistor.

4. (canceled)

5. The semiconductor device of claim 1, wherein the first section of the high resistance portion of the gate structure comprises a first material and the second section of the high resistance portion of the gate structure comprises a second material that is different from the first material.

6. The semiconductor device of claim 5, wherein the first material is doped polysilicon and the second material comprises a metal-silicon alloy.

7. The semiconductor device of claim 1, wherein the first section of the high resistance portion of the gate structure comprises a first semiconductor material that has a first doping concentration and the second section of the high resistance portion of the gate structure comprises the first semiconductor material that has a second doping concentration that is less than the first doping concentration.

8. The semiconductor device of claim 7, wherein the first semiconductor material comprises polysilicon.

9. (canceled)

10. The semiconductor device of claim 1, wherein the first section of the high resistance portion of the gate structure comprises a first semiconductor material that is doped with a first dopant type and the second section of the high resistance portion of the gate structure comprises the first semiconductor material that is doped with a second dopant type.

11. (canceled)

12. The semiconductor device of claim 1, wherein the first section of the high resistance portion of the gate structure has a positive resistance temperature coefficient and the second section of the high resistance portion of the gate structure has a negative resistance temperature coefficient.

13. (canceled)

14. The semiconductor device of claim 1, wherein the first section of the high resistance portion of the gate structure comprises a plurality of gate electrodes that are on an active region of the semiconductor layer structure and the second section of the high resistance portion of the gate structure comprises a lumped gate resistor that is on an inactive region of the semiconductor layer structure, and wherein the gate structure further comprises a metal portion that comprises a metal gate pad and a metal gate bus.

15-27. (canceled)

28. A semiconductor device, comprising:
a semiconductor layer structure; and
a gate structure that comprises a semiconductor portion on the semiconductor layer structure,
wherein the semiconductor portion of the gate structure comprises a first section that comprises a first semiconductor material and that has a first doping concentration and a first dopant type and a second section that comprises the first semiconductor material and has a second doping concentration and a second dopant type, where second doping concentration is less than the first doping concentration and/or the second dopant type is different than the first dopant type.

29. The semiconductor device of claim 28, wherein the first section of the gate structure has a first resistance temperature coefficient and the second section of the gate structure has a second resistance temperature coefficient that is at least 25% less than the first resistance temperature coefficient.

30. The semiconductor device of claim 28, wherein the first section of the gate structure comprises a plurality of gate electrodes that are on an active region of the semiconductor layer structure and the second section of the gate structure comprises one or more lumped gate resistors.

31. The semiconductor device of claim 30, wherein the gate structure further comprises a metal portion that comprises a gate pad, and the one or more lumped gate resistors are interposed on an electrical path between the gate pad and at least some of the gate electrodes.

32. The semiconductor device of claim 28, wherein the first doping concentration is at least an order of magnitude greater than the second doping concentration.

33. The semiconductor device of claim 32, wherein the first semiconductor material comprises polysilicon.

34. The semiconductor device of claim 28, wherein the first dopant type is different from the second dopant type.

35-37. (canceled)

38. A semiconductor device, comprising:
a semiconductor layer structure; and
a gate structure on the semiconductor layer structure,
wherein the gate structure comprises a first section that has a positive resistance temperature coefficient and a second section that has a negative resistance temperature coefficient.

39. The semiconductor device of claim 38, wherein the first section of the gate structure comprises a plurality of gate electrodes that are on an active region of the semiconductor layer structure and the second section of the gate structure comprises a lumped gate resistor.

40. (canceled)

41. The semiconductor device of claim 38, wherein the first section of the gate structure comprises doped polysilicon and the second section of the gate structure comprises silicon-chromium.

42-51. (canceled)
